(19) United States
(12) Patent Application Publication
(10) Pub. No.: US 2020/0029437 A1
(43) Pub. Date: Jan. 23, 2020

(54) DISPLAY DEVICE WITH ANGULAR FLEXIBLE CIRCUIT FILM

(71) Applicant: SAMSUNG DISPLAY CO., LTD., Yongin-Si (KR)

(72) Inventors: Yongsu JIN, Cheonan-Si (KR); Jinhyuk PARK, Hwaseong-Si (KR)

(21) Appl. No.: 16/405,738

(22) Filed: May 7, 2019

(30) Foreign Application Priority Data
Jul. 17, 2018 (KR) 10-2018-0082822

(51) Int. Cl. H05K 1/14; G02F 1/1345

(52) U.S. Cl. CPC H05K 1/147; H05K 2201/10136; G02F 1/13452

(57) ABSTRACT

Provided is a display device. The display device includes a display panel including a first side extending in a first direction, a plurality of printed circuit boards each facing the first side, and a plurality of flexible circuit films connected to the first side and the printed circuit boards. Lengths of the flexible circuit films in a second direction intersecting the first direction increase from a first point defined as a predetermined point of the first side to an end of the first side. First sides of at least one of the plurality of flexible circuit films connected to a printed circuit board of the plurality of printed circuit boards has a predetermined angle with respect to the first direction so as to have an inclined surface.

### CROSS-REFERENCE TO RELATED APPLICATIONS

This U.S. non-provisional patent application claims priority under 35 U.S.C. § 119 to Korean Patent Application No. 10-2018-0082822, filed on Jul. 17, 2018, the entire contents of which are incorporated by reference herein.

### 1. TECHNICAL FIELD

The present disclosure herein relates to a display device, and more particularly, to a display device with angular flexible circuit films.

### 2. DISCUSSION OF THE RELATED ART

Generally, a display device includes a display panel having a plurality of pixels arranged therein, a driver for driving pixels to display an image, and a timing controller for controlling an operation of the driver. The driver includes a gate driver disposed on a side of the display panel and connected to the scan lines, and a data driver connected to data lines that further connect to the pixel electrode.

The data driver includes a plurality of source driving chips, and the source driving chips are disposed on flexible circuit films. The timing controller is disposed on the printed circuit board. The flexible circuit films connect first sides of the display panel and the printed circuit board. The source driver chips are connected to the timing controller and display panel through the flexible circuit films. The flexible circuit films are banded and the printed circuit board is disposed at a lower part of the display panel.

In general, a display device has traditionally been manufactured in a flat shape, but a display device having a curved surface shape has been recently developed. As a display panel in a flat state is bent into a curved shape, a curved display device may be manufactured. However, when the display panel is bent into a curved surface shape, flexible circuit films may be detached from the display panel due to stresses occurring in the flexible circuit films connected to the display panel.

### SUMMARY

The present disclosure relates to a display device including an angular flexible circuit film.

According to an exemplary embodiment of the present inventive concept a display device includes a display panel. The display panel includes a first side extending in a first direction and a plurality of printed circuit boards facing the first side. A plurality of flexible circuit films connect the first side and the printed circuit boards. Lengths of the flexible circuit films in a second direction intersecting the first direction increase from a first point defined as a predetermined point of the first side to an end of the first side. First sides of the at least one flexible circuit film connected to a printed circuit board of the plurality of printed circuit boards has a predetermined angle with respect to the first direction so as to have an inclined surface.

### BRIEF DESCRIPTION OF THE FIGURES

The above described and other aspects of the present inventive concept will become more apparent by the following description of exemplary embodiments thereof in conjunction with the attached drawings, in which:

FIG. 1 is a perspective view of a display device according to an exemplary embodiment of the present inventive concept;

FIG. 2 is a perspective view illustrating a configuration of a pixel shown in FIG. 1;

FIG. 3 is a plan view of the display device shown in FIG. 1;

FIG. 4 is a perspective view showing a state where the display panel shown in FIG. 3 is deformed into a curved surface and the first and second flexible circuit films are bent;

FIG. 5 is a perspective view showing a flexible circuit film;

FIG. 6 is a perspective view showing a first flexible circuit film attached at one end to the first substrate among the first flexible circuit films shown in FIG. 4, and attached to the printed circuit board at the other end;

FIG. 7 is an enlarged view of a connection region between the first flexible circuit film and the first printed circuit board shown in FIG. 6; and

FIGS. 8 to 10 are perspective views showing flexible circuit films attached to printed circuit boards of a display device according to exemplary embodiments of the present inventive concept.

### DETAILED DESCRIPTION

In the following detailed description, when it is mentioned that a component (or, an area, a layer, a part, etc.) is “disposed on”, “connected to” or “combined to” another component, it may mean either that intervening layers are present between the components or that the components are disposed “directly on” one another.

Like reference numerals may refer to like elements throughout the detailed description. Additionally, in the drawings, the thicknesses, proportions, and dimensions of components may be exaggerated for effective description.

It will be understood that the terms “first” and “second” are used herein to describe various components but these components should not be limited by these terms. The above terms are used only to distinguish one component from another. For example, a first component may be referred to as a second component and vice versa without departing from the scope of the inventive concept. The singular expressions include plural expressions unless the context clearly dictates otherwise.

In addition, terms such as “below”, “the lower side”, “on”, and “the upper side” are used to describe a relationship of configurations shown in the drawing. The terms are described as a relative concept based on a direction shown in the drawing.

Hereinafter, exemplary embodiments of the present inventive concept are described in more detail with reference to the accompanying drawings.

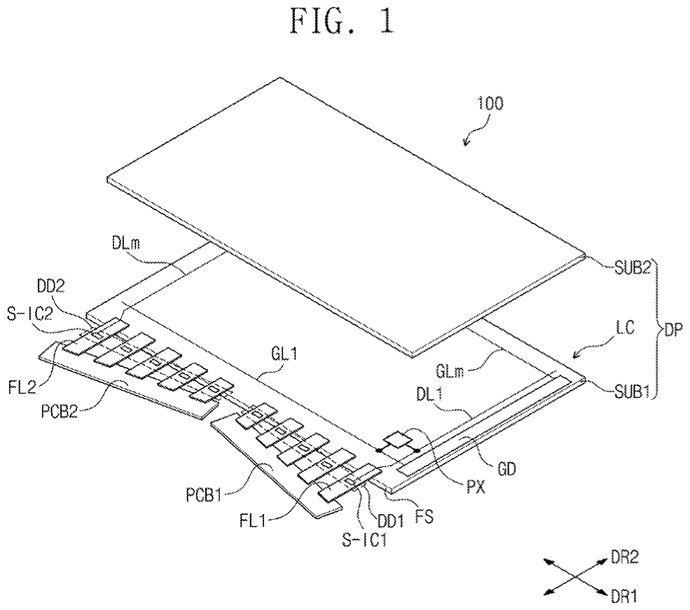

FIG. 1 is a perspective view of a display device according to an exemplary embodiment of the present inventive concept.

Referring to FIG. 1, a display device 100 according to an exemplary embodiment of the present inventive concept includes a display panel DP, a gate driver GD, a plurality of printed circuit boards PCB1 and PCB2, a plurality of data drivers DD1 and DD2, and a plurality of flexible circuit films FL1 and FL2.

The display panel DP may have a rectangular shape having long sides in a first direction DR1 and short sides in a second direction DR2 that intersect the first direction DR1.

The display panel DP includes a first substrate SUB1, a second substrate SUB2 facing the first substrate SUB1, and a liquid crystal layer LC disposed between the first substrate SUB1 and the second substrate SUB2. The first and second substrates SUB1 and SUB2 may each include a transparent organic substrate or a plastic substrate. Each of the first and second substrates SUB1 and SUB2 may have a substantially rectangular shape having a pair of long sides extending in the first direction DR1 and a pair of short sides extending in the second direction DR2.

A liquid crystal display panel DP including a liquid crystal layer LC is shown in FIG. 1. However, the inventive concept is not limited thereto, and various other types of display panels for displaying images may be used as the display panel DP. For example, the display panel DP may be an organic light emitting display panel, an electrophoretic display panel, and/or an electrowetting display panel.

A plurality of pixels PX, a plurality of gate lines GL1 to GLm, and a plurality of data lines DL1 to DLm may be disposed on the first substrate SUB1. Here, m and n are positive integers. For convenience of explanation and illustration, only one pixel PX is shown in FIG. 1, but a plurality of pixels PX may be disposed on the first substrate SUB1.

The gate lines GL1 to GLm may extend in the first direction DR1 and may be connected to a gate driver GD. The data lines DL1 to DLm may extend in the second direction DR2 and may be connected to the data drivers DD1 and DD2. The gate lines GL1 to GLm and the data lines DL1 to DLm may be insulated from each other and intersect each other. The pixels PX may be arranged in a matrix form and connected to the gate lines GL1 to GLm and the data lines DL1 to DLm.

The gate driver GD may be disposed in a predetermined region of the first substrate SUB1 adjacent to one side of the first substrate SUB1. One side of the first substrate SUB1 may be defined as one of the short sides of the first substrate SUB1. The gate driver GD is formed at the same time as the transistors of the pixels PX and is mounted on the first substrate SUB1 and may include an amorphous silicon TFT gate driver circuit (ASG) or an oxide silicon TFT gate driver (OSG).

However, the inventive concept is not limited thereto, and the gate driver GD may include a plurality of gate driving chips, and the gate driving chips may be mounted on the flexible circuit film. The flexible circuit films may be connected at an end to the first substrate SUB1 and the gate driving chips may be connected to the first substrate SUB1 through the flexible circuit films. Alternatively, the plurality of gate driving chips may be mounted on the first substrate SUB1 by a chip on glass (COG) method.

The data drivers DD1 and DD2 may include a plurality of source driving chips S-IC1 and S-IC2. The plurality of source driving chips S-IC1 and S-IC2 may be disposed on the flexible circuit films FL1 and FL2, respectively.

The flexible circuit films FL1 and FL2 may overlap the first side FS of the display panel DP. The first side FS of the display panel DP is defined as any one long side of the long sides of the display panel DP and may define one side FS of the first substrate SUB1. The first side FS of the display panel DP may extend in the first direction DR1.

The flexible circuit films FL1 and FL2 may each extend in the second direction DR2 and may be spaced apart from one another in the first direction DR1. The flexible circuit films FL1 and FL2 may be connected to the printed circuit boards PCB1 and PCB2 and the display panel DP. For example, the flexible circuit films FL1 and FL2 may bridge a gap between the printed circuit boards PCB1 and PCB2 and the display panel DP. The source driving chips S-IC1 and S-IC2 may be connected to the printed circuit boards PCB1 and PCB2 and the display panel DP through the flexible circuit films FL1 and FL2. For example, the source driving chips S-IC1 and S-IC2 may be disposed in the middle of the flexible circuit films FL1 and FL2, respectively, to overlap the gap formed between the printed circuit board PCB1 and the first substrate SUB1.

First sides of the flexible circuit films FL1 and FL2 may be connected to the printed circuit boards PCB1 and PCB2 and the second side of the flexible circuit films FL1 and FL2 may be connected to the first side FS of the display panel DP. The second side of each of the flexible circuit films FL1 and FL2 may be opposite to the first sides of each of the flexible circuit films FL1 and FL2. For example, each of the flexible circuit films FL1 and FL2 may connect to a printed circuit board PCB1 and PCB2 respectively at a first end, and connect to the first substrate SUB1 at a second end adjacent to the first side FS of the display panel DP.

The printed circuit boards PCB1 and PCB2 may include a first printed circuit board PCB1 and a second printed circuit board PCB2. The data drivers DD1 and DD2 may include a first data driver DD1 connected to the first printed circuit board PCB1 and a second data driver DD2 connected to the second printed circuit board PCB2.

For example, the display panel DP may be divided into a first area and a second area. The first data driver DD1 may be connected to the pixels PX of the first area of the display panel DP. The second data driver DD2 may be connected to the pixels PX of the second area of the display panel DP.

The first data driver DD1 may include a plurality of first source driving chips S-IC1 and the second data driver DD2 may include a plurality of second source driving chips S-IC2. For example, DD1 and DD2 may represent the collective array of the plurality of S-IC1 and S-IC2, respectively. The flexible circuit films FL and FL2 may include a plurality of first flexible circuit films FL1 and a plurality of second flexible circuit films FL2. The first source driving chips S-IC1 may be disposed on the first flexible circuit films FL1 and the second source driving chips S-IC2 may be disposed on the second flexible circuit films FL2. The first flexible circuit films FL1 may be connected to the first printed circuit board PCB1 and the first side FS of the display panel DP. The first source driving chips S-IC1 may be connected to the first printed circuit board PCB1 and the display panel DP through the first flexible circuit films FL1.

The second flexible circuit films FL2 may be connected to the first printed circuit board PCB2 and the first side FS of the display panel DP. The second source driving chips S-IC2 may be connected to the second printed circuit board PCB2 and the display panel DP through the second flexible circuit films FL2.

Timing controllers may be disposed on the printed circuit boards PCB1 and PCB2. The timing controllers may be mounted on printed circuit boards PCB1 and PCB2 in the form of integrated circuit chips and connected to data drivers DD1 and DD2. For example, a timing controller disposed on the first printed circuit board PCB1 is connected to the first data driver DD1, and a timing controller disposed on the second printed circuit board PCB2 may be connected to the second data driver DD2.

The timing controllers may output the data control signal and the image data. A timing controller may be connected to the gate driver GD through a flexible circuit films (e.g., the flexible circuit film FL1 disposed at the rightmost side) and may output a gate control signal.

The gate driver GD may receive a gate control signal and may generate a plurality of gate signals in response to the gate control signal. The gate driver GD may sequentially output the gate signals. The gate signals may be provided to the pixels PX by a row unit through the gate lines GL1 to GLm. As a result, the pixels PX may be driven by the row unit.

The data drivers DD and DD2 may receive the image data and the data control signal. The data drivers DD1 and DD2 may generate and output analog data voltages corresponding to the image data in response to the data control signal. The data voltages may be provided to the pixels PX through the data lines DL1 to DLm.

The pixel PX may receive data voltages through the data lines DL1 to DLm in response to gate signals provided through the gate lines GL1 to GLm. As the pixel PX displays the grayscales corresponding to the data voltages, an image may be displayed.

A backlight unit may be disposed at the back of the display panel DP. The backlight unit may generate light and provide it to the display panel DP. The display panel DP may generate an image using the light provided from the backlight unit.

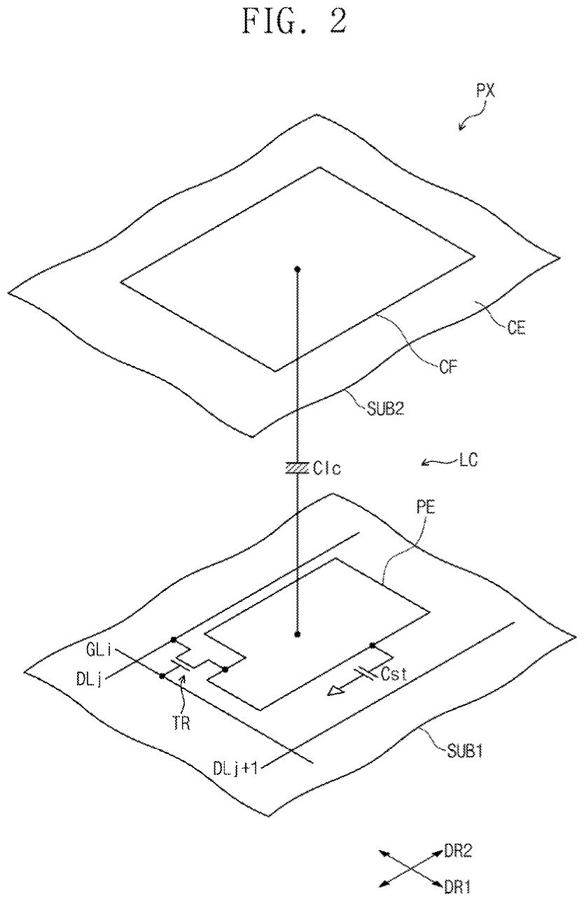

FIG. 2 is a perspective view illustrating a configuration of a pixel shown in FIG. 1.

For convenience of description, in FIG. 2, a pixel PX connected to the gate line GLi and the data line DLj is shown, and the configuration of the other pixels PX included in the display panel DP will be the same as that of the pixel PX shown in FIG. 2.

Referring to FIG. 2, the pixel may include a transistor TR connected to the gate line GLi and the data line DLj, a liquid crystal capacitor Clc connected to the transistor TR, and a storage capacitor Cst connected in parallel to the liquid crystal capacitor Clc. The storage capacitor Cst may be omitted. Here i and j are positive integers.

The transistor TR may be disposed on the first substrate SUB1. The transistor TR may include a gate electrode connected to the gate line GLi, a source electrode connected to the data line DLj, and a drain electrode connected to the liquid crystal capacitor Clc and the storage capacitor Cst.

The liquid crystal capacitor Clc may include a pixel electrode PE disposed on the first substrate SUB1, a common electrode CE disposed on the second substrate SUB2, and a liquid crystal layer LC disposed between the pixel electrode PE and the common electrode CE. The liquid crystal layer LC serves as a dielectric. The pixel electrode PE may be connected to the drain electrode of the transistor TR.

The pixel electrode PE has a non-slit structure in FIG. 2 but the inventive concept is not limited thereto. Thus, the pixel PE may have a slit structure including a cross-shaped branch part and a plurality of branch parts extending radially from the cross-shaped branch part.

The common electrode CE may be disposed on the entire lower part of the second substrate SUB2. However, the inventive concept is not limited thereto, and the common electrode CE may be disposed on the first substrate SUB1. In such a case, at least one of the pixel electrode PE and the common electrode CE may include a slit.

The storage capacitor Cst may include a pixel electrode PE, a storage electrode branched from a storage line, and an insulation layer disposed between the pixel electrode PE and the storage electrode. The storage line may be disposed on the first substrate SUB1 and may be formed on the same layer as the gate lines GL1 to GLm. The storage electrode may partially overlap the pixel electrode PE.

The pixel PX may further include a color filter CF representing one of red, green, and blue colors. According to an exemplary embodiment of the present inventive concept, as shown in FIG. 2, the color filter CF may be disposed on the second substrate SUB2. However, the inventive concept is not limited thereto. For example, the color filter CF may be disposed on the first substrate SUB1.

The transistor TR is turned on in response to receiving a gate signal provided through the gate line GLi. The data voltage received via the data line DLj may be provided to the pixel electrode PE of the liquid crystal capacitor Clc through the turned-on transistor TR. A common voltage may be applied to the common electrode CE.

An electric field may be formed between the pixel electrode PE and the common electrode CE due to a difference in the voltage levels between a data voltage and a common voltage. The liquid crystal molecules of the liquid crystal layer LC may be driven by an electric field generated between the pixel electrode PE and the common electrode CE. The light transmittance is adjusted by the liquid crystal molecules driven by the electric field, so that an image may be displayed.

A storage voltage having a constant voltage level may be applied to a storage line. However, the inventive concept is not limited thereto, and the storage line may have the common voltage applied rather than the storage voltage. The storage capacitor Cst may serve to compensate the charged amount of the liquid crystal capacitor Clc.

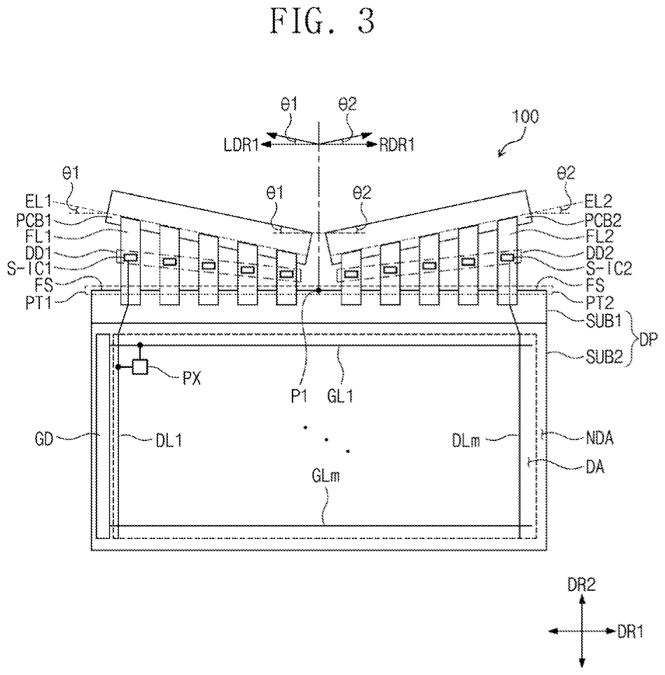

FIG. 3 is a plan view of the display device according to the exemplary embodiment of the present invention shown in FIG. 1.

Referring to FIG. 3, a predetermined point of the first side FS of the display panel DP may be defined as a first point P1. For example, the first point P1 may be disposed at the center of the first side FS on an edge of the first side FS, but the position of the first point P1 is not limited thereto.

The first side FS may include a first part PT1 extending along an edge of the first side FS from the first point P1 to one end of the first side FS and a second part PT2 extending along an edge of the first side FS from the first point P1 to the opposite end of the first side FS. For example, one end of the first side FS may correspond to the left side of the first side FS, and the other end of the first side FS may correspond to the right side of the first side FS. The end of the first part PT1 may be one end of the first side FS and the end of the second part PT2 may be the other end of the first side FS.

The first printed circuit board PCB1 may be spaced apart from the first part PT1 and may face the first part PT1. The second printed circuit board PCB2 may be spaced apart from the second part PT2 and may face the second part PT2. For example, the first and second printed circuit boards PCB1 and PCB2 may be spaced apart from the first side FS at a distance which increases further away from the first point P1 towards an end of the first side FS.

The first flexible circuit films FL may be connected at one end to the first part PT1 of the first side FS and the first printed circuit board PCB1 at the other end. The second flexible circuit films FL2 may be connected at one end to the second part PT2 of the first side FS and the second printed circuit board PCB2 at the other end. For example, the flexible circuit films FL1 and FL2 may bridge a gap between the printed circuit boards PCB1 and PCB2 and the first side FS.

The lengths of the flexible circuit films FL1 and FL2 may vary among flexible circuit films. For example, the lengths of the flexible circuit films FL1 and FL2 in the second direction DR2 may be longer in those that are spaced further from the first point P1 in a direction towards a first and second end of the first part PT1 and second part PT2, respectively. For example, the lengths of the flexible circuit films FL1 and FL2 may become longer in the second direction DR2 when spaced further apart from the center of the first side FS towards the left and right ends thereof. For example, the lengths of the first flexible circuit films FL1 and FL2 may become longer as they approach from the first point P1 to one end of the first side FS. The lengths of the second flexible circuit films FL2 may become longer as they approach from the first point P1 to the other end of the first side FS.

A side of the first printed circuit board PCB1 may be further separated from the first part PT1 in a direction from the first point P1 towards an end of the first side FS. A side of the second printed circuit board PCB2 may be further separated from the second part PT2 in a direction from the first point P1 to the other end of the first side FS. For example, the lengths of the flexible circuit films FL1 and FL2 in the second direction DR2 may increase in proportion to the distance of the first and second printed circuit boards PCB1 and PCB2 from the first side FS at that location.

First sides of the first and second flexible circuit films FL1 and FL2 connected to the first and second printed circuit boards PCB1 and PCB2, respectively, may extend at a predetermined angle with respect to the first direction DR1 so as to have inclined surfaces opposite to each other with respect to the first point P1. For example, an end of each of the flexible circuit films FL1 and FL2 attached to the printed circuit board PCB1 and PCB2, respectively, may be sloped by a predetermined angle with respect to a plane parallel to a surface of the first side FS.

First sides of the first flexible circuit films FL1 connected to the first printed circuit board PCB1 may form a first angle θ1 smaller than 90 degrees with respect to a plane parallel to a surface of the first part PT1 based on the first point P1. First sides of the second flexible circuit films FL2 connected to the second printed circuit board PCB2 may form a second angle θ2 smaller than 90 degrees with respect to a plane parallel to a surface of the second part PT2 based on the first point P1. Hereinafter, a direction parallel to the direction from the first point P1 to one end of the first side FS is defined as a left direction LDR1, and a direction parallel to the direction from the first point P1 to the other end of the first side FS is defined as the right direction RDR1. The first direction DR1 may include the left direction LDR1 and the right direction RDR1.

First sides of the first flexible circuit films FL1 may be formed as an inclined surface forming the first angle θ1 with respect to the left direction LDR1. First sides of the second flexible circuit films FL2 may be formed as an inclined surface forming the second angle θ2 with respect to the right direction RDR1. θ1 and θ2 may have an initial ray that is parallel to a surface of the first side and a terminal ray that extends away from the first point. For example θ1 and θ2 may have an initial ray that is parallel to a plane of the left and right directions LDR1 and RDR1, respectively, and a terminal ray that extends away from the first point.

The first flexible circuit films FL1 may have first sides disposed on the first same line. For example, a virtual line may extend through the terminal ray of the first angle θ1 with respect to the left direction LDR1 towards the first point P1 and may be defined as a first extension line EL1.

The first extension line EL1 may be an extension line adjacent to one side of the first printed circuit board PCB1 facing the first part PT1 and intersecting the first printed circuit board PCB1. First sides of the first flexible circuit films FL1 may extend along the first extension line EL1. The first extension line EL1 may be defined as a first same line EL1.

First sides of the second flexible circuit films FL2 may be disposed on the second same line. For example, a virtual line forming the second angle θ2 with respect to the right direction RDR1 based on the first point P1 and extending may be defined as a second extension line EL2.

The second extension line EL2 may be an extension line adjacent to one side of the second printed circuit board PCB2 facing the second part PT2 and intersecting the second printed circuit board PCB2. First sides of the second flexible circuit films FL2 may extend along the second extension line EL2. The second extension line EL2 may be defined as a second same line EL2.

Unlike the first sides of the first and second flexible circuit films FL1 and FL2, each of the second sides of the first and second flexible circuit films FL1 and FL2 connected to the display panel DP may be parallel to the first direction DR1.

According to an exemplary embodiment of the inventive concept, the first angle θ1 may be equal to the second angle θ2. In this case, first sides of the first flexible circuit films FL1 may be symmetrical with first sides of the second flexible circuit films FL2. For example, the first angle θ1 and the second angle θ2 may be 2 degrees to 10 degrees. However, the inventive concept is not limited thereto, and the first angle θ1 may be different from the second angle θ2. In this case, first sides of the first flexible circuit films FL1 might not be symmetrical with first sides of the second flexible circuit films FL2.

According to an exemplary embodiment of the present inventive concept, the first flexible circuit films FL1 may have a collective shape which is substantially symmetrical with the collective shape of the second flexible circuit films FL2. However, the inventive concept is not limited thereto, and the first flexible circuit films FL1 might not have a symmetrical shape with respect to the second flexible circuit films FL2, respectively.

The first printed circuit board PCB1 may be inclined by the first angle θ1 with respect to a plane parallel to a surface of the first part PT1. For example, the first printed circuit board PCB1 may form the first angle θ1 with respect to the left direction LDR1 based on the first point P1.

The second printed circuit board PCB2 may be inclined to form the second angle θ2 with respect to a plane parallel to a surface of the second part PT2. For example, the second printed circuit board PCB2 may form the second angle θ2 with respect to the right direction RDR1 based on the first point P1.

According to an exemplary embodiment of the present inventive concept, the first printed circuit board PCB1 may have a shape symmetrical with the second printed circuit board PCB2. However, the inventive concept is not limited thereto, and the first printed circuit board PCB1 might not be symmetrical with the second printed circuit board PCB2.

Each of the first and second printed circuit boards PCB1 and PCB2 may have a rectangular shape. For example, the rectangular long sides of the first printed circuit board PCB1 may be sloped by the first angle θ1 with respect to the first part PT1. The rectangular long sides of the second printed circuit board PCB2 may be sloped by the second angle θ2 with respect to the second part PT2. For example, the angles θ1 and 02 may each have a terminal ray and an initial ray that extend in a direction away from the first point P1.

The rectangular short sides extend perpendicular to the rectangular long sides at the ends of the rectangular long sides. For example, the rectangular short sides of the first printed circuit board PCB1 intersect perpendicularly to the extending directions of the long sides of the first printed circuit board PCB1 and extend at the ends of the long sides of the first printed circuit board PCB1. The rectangular short sides of the second printed circuit board PCB2 intersect perpendicularly to the extending directions of the long sides of the second printed circuit board PCB2 and extend at the ends of the long sides of the second printed circuit board PCB2.

The first and second source driving chips S-IC1 and S-IC2 may be disposed at the central parts of the first and second flexible circuit films FL1 and FL2, respectively, based on the second direction DR2. The central parts of the first and second flexible circuit films FL1 and FL2 may be defined as bending parts.

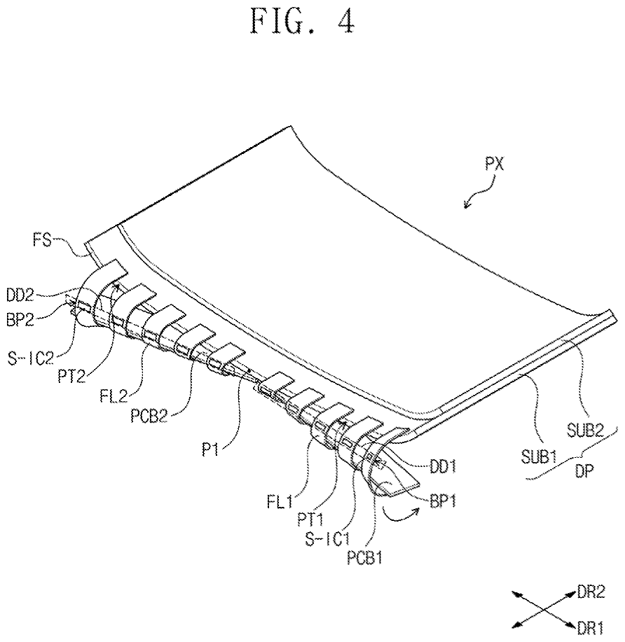

FIG. 4 is a view showing a state where the display panel shown in FIG. 3 is deformed into a curved surface and the first and second flexible circuit films are bent.

For convenience of description, in FIG. 4, the first substrate SUB1 and the second substrate SUB2 are shown as being bonded together, and the pixels PX, the gate driver GD, and the gate and data lines GL1 to GLm and DL1 to Dlm are not shown.

Referring to FIG. 4, the display device 100 may be a curved display device 100. For example, the display panel DP may be bent with respect to the first direction DR1 and may remain flat with respect to the second direction DR2. The curvature of the display panel DP may become larger toward both sides of the display panel DP based on the first direction DR1. For example, the display panel DP may be increasingly bent towards both sides of the display panel DP.

The first and second flexible circuit films FL1 and FL2 may be bent towards the lower surface of the display panel DP. The first and second flexible circuit films FL1 and FL2 are bent so that the first and second printed circuit boards PCB1 and PCB2 may at least partially overlap the lower surface of the display panel DP.

For example, the center parts of the first flexible circuit films FL1 with respect to the second direction DR2 may be defined as first bending parts BP1. The first bending parts BP1 may substantially overlap parts of the first flexible circuit films FL1 on which the first source driving chips S-IC1 are disposed.

The center parts of the second flexible circuit films FL2 with respect to the second direction DR2 may be defined as second bending parts BP2. Substantially, the second bending parts BP2 may overlap parts of the second flexible circuit films FL2 on which the second source driving chips S-IC2 are disposed.

The first flexible circuit films FL1 may be bent with respect to the first bending parts BP1 toward the lower part of the display panel DP. The second flexible circuit films FL2 may be bent with respect to the second bending parts BP2 toward the lower surface of the display panel DP.

As the first and second bending parts BP1 and BP2 are bent, the first and second printed circuit boards PCB11 and PCB2 may be disposed at the lower surface of the display panel DP. Therefore, the first and second printed circuit boards PCB1 and PCB2 might not be exposed.

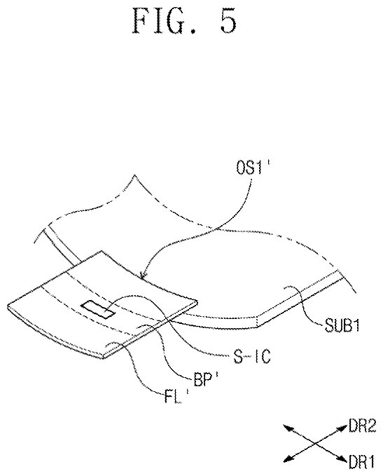

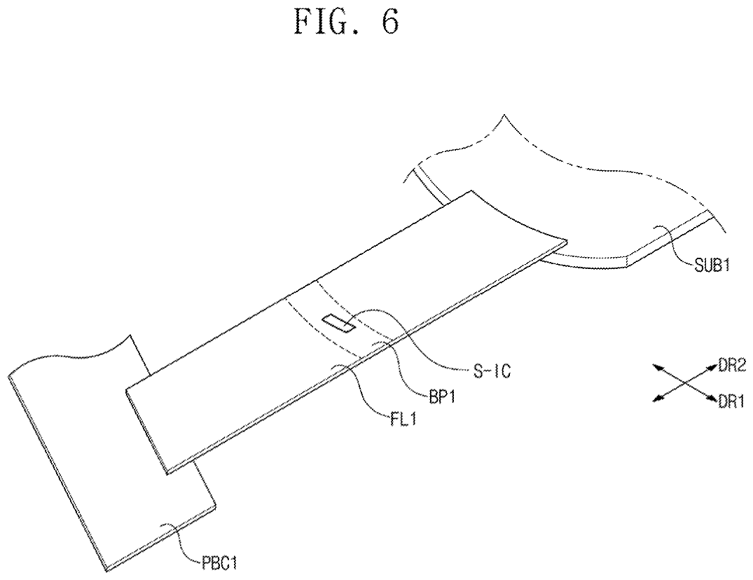

FIG. 5 is a perspective view illustrating a comparative flexible circuit film. FIG. 6 is a perspective view showing a first flexible circuit film from among the first flexible circuit films shown in FIG. 4 attached at one end to the first substrate and attached to the printed circuit board at the other end;

Referring to FIG. 5, the display panel DP may be bent, and the first substrate SUB1 may be more curved toward both sides of the first substrate SUB1. The comparative flexible circuit film FL′ may be connected to a part of the first substrate SUB1 adjacent to one side of the first substrate SUB1 having the largest curvature in the first substrate SUB1.

The comparative flexible circuit film FL′ may have a length smaller than that of each of the first flexible circuit films FL1 based on the second direction DR2. The comparative flexible circuit film FL′ may be bent around the bending part BP′ of the comparative flexible circuit film FL′ adjacent to one side of the first substrate SUB1. The bending part BP′ may be nearer to the first substrate SUB1 than the first and second bending parts BP1 and BP2.

When the comparative flexible circuit film FL′ is spread flat, the comparative flexible circuit film FL′ may be easily bent toward the lower part of the display panel DP. However, the comparative flexible circuit film FL′ connected to the curved first substrate SUB1 is deformed into a curved shape corresponding to the first substrate SUB1.

Stronger forces may be required to bend the bent flexible circuit film FL′. However, in this case, a stronger stress may be generated on one side OS1′ of the comparative flexible circuit film FL′ connected to one side of the first substrate SUB1. One side OS1′ of the comparative flexible circuit film FL′ may separate from the first substrate SUB1 due to the stress.

As described above, the first substrate SUB1 may be bent more greatly toward one end and the other end of the first substrate SUB1. Therefore, when a plurality of comparative flexible circuit films FL′ are connected to the first substrate SUB1, as approaching one end and the other end of one side of the first substrate SUB1, larger stresses may occur in the comparative flexible circuit films FL′.

Referring to FIG. 6, one side of the first flexible circuit film FL1 is connected to the first printed circuit board PCB1 that is in a flat state, and the second side of the first flexible circuit film FL1 may be connected to the bent first substrate SUB1. The first flexible circuit film FL1 shown in FIG. 6 may have the longest length among the first flexible circuit films FL1 and may be disposed at a curved edge of the first substrate SUB1. The part of the first flexible circuit film FL1 adjacent to the first substrate SUB1 may be bent like the first substrate SUB1. However, as it extends farther from the first substrate SUB1, the first flexible circuit film FL1 may be bent less. In addition, by extending the length of the first flexible circuit film FL1, the first bending part BP1 may be further separated from the first substrate SUB1 than the bending part BP′.

Based on the first bending part BP1 of the first flexible circuit film FL1, which is less bent and further spaced from the first substrate SUB1, the first flexible circuit film FL1 may be bent. As a result, the stress on the first flexible circuit film FL1 connected to the first substrate SUB1 may be decreased.

As described above, the first substrate SUB1 is bent more greatly at ends of a side of the first substrate SUB1. As the first substrate SUB1 is bent, stress may be generated. According to an exemplary embodiment of the present inventive concept, since the lengths of the first and second flexible circuit films FL1 and FL2 become longer toward one end and the other end of the first substrate SUB1, the stresses of the first and second flexible circuit films FL1 and FL2 may be decreased in proportion to the degree of bending of the first substrate SUB1.

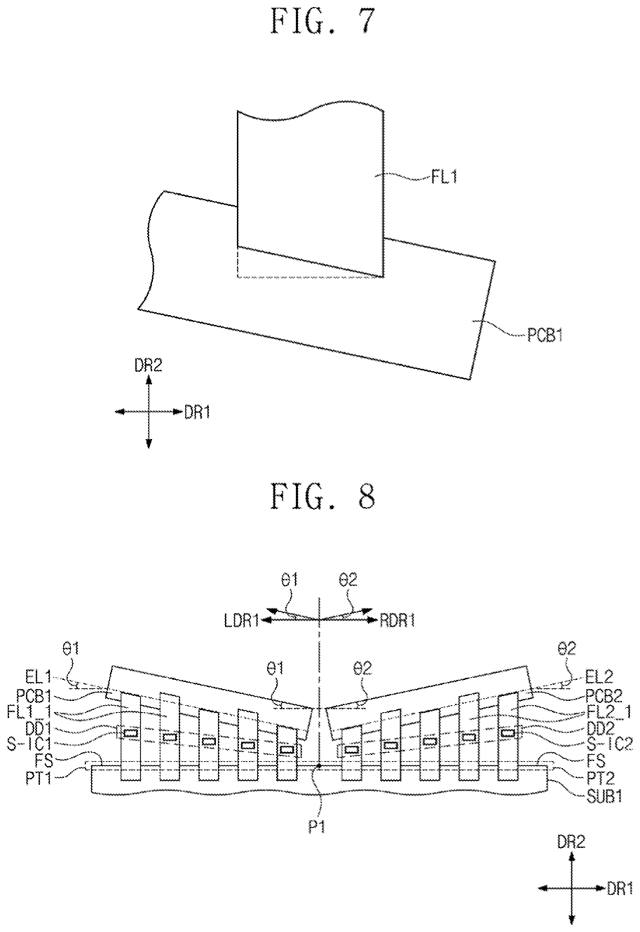

FIG. 7 is an enlarged view of a connection between the first flexible circuit film and the first printed circuit board shown in FIG. 6.

Referring to FIG. 7, if one side of the first flexible circuit film FL1 does not have an inclined surface and has a rectangular shape shown by a dotted line, the first flexible circuit film FL1 may occupy a greater part of the first printed circuit board PCB1. In addition to the timing controller, various electronic devices may be disposed on the first printed circuit board PCB1. If the first flexible circuit film FL1 has a rectangular shape, the space (or mounting area) for disposing the timing controller and various electronic elements may be less available.

However, in the exemplary embodiment of the present inventive concept, one side of the first flexible circuit film FL1 has an inclined surface, the first flexible circuit film FL1 therefore occupies a smaller part of the first printed circuit board PCB1. Thus, more space may be secured for arranging the timing controller and various electronic elements.

As a result, the display device 100, according to an exemplary embodiment of the present inventive concept, may also reduce the stress on the flexible circuit films FL1 and FL2 and further secure the mounting area of the printed circuit boards PCB1 and PCB2.

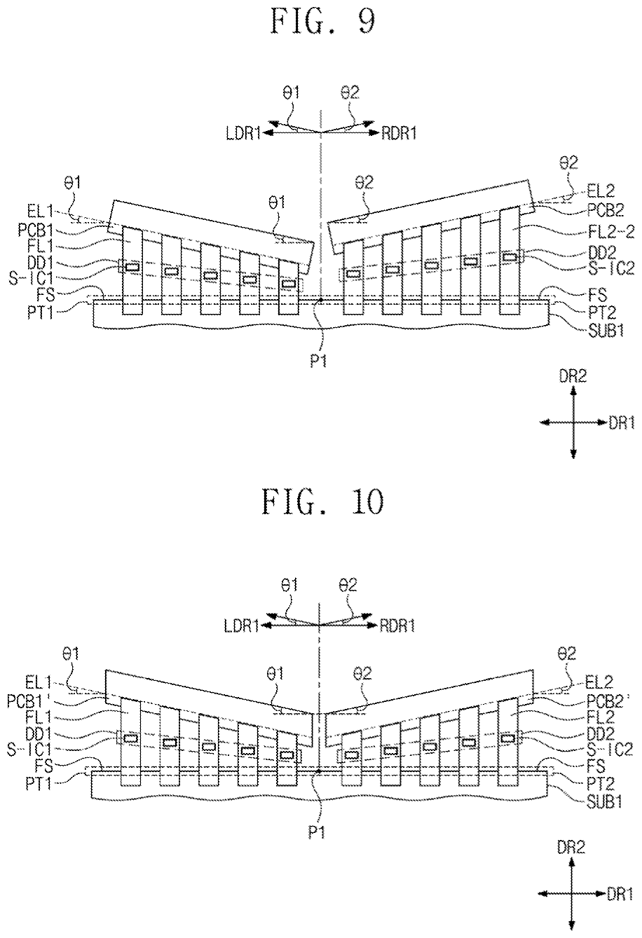

FIGS. 8 to 10 are perspective views showing flexible circuit films and printed circuit boards of display devices according to exemplary embodiments of the present inventive concept.

Except for the flexible circuit films FL1_1, FL2_1 and FL2_2 shown in FIGS. 8 and 9 and the printed circuit boards PCB1′ and PCB2′ shown in FIG. 10, the display devices according to other exemplary embodiments of the present inventive concept may have substantially the same configuration as the display device 100 shown in FIGS. 1 and 3.

Hereinafter, with reference to FIGS. 8 to 10, the configuration of the flexible circuit films FL1_1, FL2_1 and FL2_2 and the printed circuit boards PCB1′ and PCB2′ will be described, and the same components are denoted by the same reference numerals shown in FIGS. 1 and 3.

For convenience of description, a part of the first substrate SUB1 connected to the flexible circuit films FL1_1, FL2_1, FL2_2 is shown in FIGS. 8 to 10.

Referring to FIG. 8, some of the first sides of the first flexible circuit films FL1_1 may be disposed on the first same line and the rest might not be disposed on the first same line. For example, among the first flexible circuit films FL1_1, the odd-numbered first flexible circuit films FL1_1 may overlap the first extension line EL1, and the even-numbered first flexible circuit films FL1_1 might not overlap the first extension line EL1.

Some of first sides of the second flexible circuit films FL2_1 may be disposed on the second same line and the rest might not be disposed on the second same line. For example, among the second flexible circuit films FL2_1, the odd-numbered second flexible circuit films FL2_1 may overlap the second extension line EL2, and the even-numbered second flexible circuit films FL2_1 might not overlap the second extension line EL2. According to an exemplary embodiment of the present invention, first and second flexible circuit films FL1_1 and FL2_1 may have a staggered formation.

Referring to FIG. 9, the first flexible circuit films FL1 may be spaced apart from one another at positions corresponding to the positions of second flexible circuit films FL2_2. For example, the positions at which the first flexible circuit films FL1 are arranged with respect to the first point P1 may be symmetrical to the positions at which the second flexible circuit films FL2_2 are spaced apart from one another.

Each of the first flexible circuit films FL1 may have a length smaller than that of the second flexible circuit films FL2_2 disposed at corresponding positions among the second flexible circuit films FL2_2. For example, the first flexible circuit film FL1 adjacent to one end of the first side FS may have a length less than that of the second flexible circuit film FL2 adjacent to the other end of the first side FS. Referring to FIG. 10, each of the first and second printed circuit boards PCB1′ and PCB2′ may have a parallelogram shape. The long sides of the parallelogram of the first printed circuit board PCB1′ may form the first angle θ1 with respect to a plane parallel to a surface of the first part PT). The short sides of the parallelograms of the first printed circuit board PCB1′ may extend in the second direction DR2 from the ends of the long sides of the first printed circuit board PCB1′.

The long sides of the parallelograms of the second printed circuit board PCB2′ may form the second angle θ2 with respect to a plane parallel to a surface of the first part PT2. The short sides of the parallelograms of the second printed circuit board PCB2′ may extend in the second direction DR2 from the ends of the long sides of the second printed circuit board PCB2′ and extend. The short sides of the first and second printed circuit boards PCB1′ and PCB2′ might not be perpendicular to the long sides.

The display device according to an embodiment of the inventive concept may reduce the stress of the flexible circuit films by increasing the length of the flexible circuit films towards ends of the curved display panel.

In addition, the display device according to the exemplary embodiment of the present inventive concept may further preserve the mounting area of the printed circuit boards by forming one side of the flexible circuit films connected to the printed circuit boards with an inclined surface.

Although the exemplary embodiments of the inventive concept have been described, it is understood that the inventive concept should not be limited to these exemplary embodiments but various changes and modifications can be made by one ordinary skilled in the art within the spirit and scope of the inventive concept.

What is claimed is:

1. A display device comprising:
a display panel including a first side extending in a first direction;
a plurality of printed circuit boards each facing the first side; and
a plurality of flexible circuit films connected to the first side and the printed circuit boards,
wherein lengths of the flexible circuit films in a second direction intersecting the first direction increase from a first point defined as a predetermined point of the first side to towards ends of the first side,
wherein a first side of at least one flexible circuit film of the plurality of flexible circuit films connected to a printed circuit board of the plurality of printed circuit boards has a predetermined angle with respect to the first direction so as to have an inclined surface.

2. The display device of claim 1, wherein the first side comprises:
a first part extending from the first point to an end of the first side; and
a second part extending from the first point to an opposite end of the first side.

3. The display device of claim 2, wherein the printed circuit boards comprise:
a first printed circuit board facing the first part; and
a second printed circuit board facing the second part,
wherein the plurality of flexible circuit films comprises:
a plurality of first flexible circuit films connected to the first printed circuit board and the first part; and
a plurality of second flexible circuit films connected to the second printed circuit board and the second part.

4. The display device of claim 3, wherein lengths of the first flexible circuit films increase from the first point to the end of the first side, and lengths of the second flexible circuit films increase from the first point to the opposite end of the first side.

5. The display device of claim 3, wherein the first printed circuit board is further away from the first part in a direction extending from the first point to the end of the first side, and the second printed circuit board is further away from the second part in a direction extending from the first point to the opposite end of the first side.

6. The display device of claim 3, wherein the first flexible circuit films have a collective shape that is symmetrical to the collective shape of the second flexible circuit films, and the first printed circuit board has a shape that is symmetrical to the shape of the second printed circuit board.

7. The display device of claim 3, wherein first sides of the first flexible circuit films connected to the first printed circuit board form a first angle that is less than 90 degrees with respect to a plane parallel to a surface of the first part, and
wherein first sides of the second flexible circuit films connected to the second printed circuit board form a second angle less than 90 degrees with respect to a plane parallel to a surface of the second part.

8. The display device of claim 7, wherein the first sides of the first flexible circuit films are disposed on a same first line as a terminal ray of the first angle.

9. The display device of claim 7, wherein the first sides of the second flexible circuit films are disposed on a same second line as a terminal ray of the second angle.

10. The display device of claim 7, wherein some of the first sides of the first flexible circuit films are disposed on the first same line and the rest are not disposed on the first same line, and
wherein some of the first sides of the second flexible circuit films are disposed on the second same line and the rest are not disposed on the second same line.

11. The display device of claim 7, wherein the first angle is the same as the second angle.

12. The display device of claim 7, wherein the first angle and the second angle are each between 2 degrees to 10 degrees.

13. The display device of claim 7, wherein the first angle is different from the second angle.

14. The display device of claim 7, wherein the first printed circuit board is inclined by the first angle with respect to the plane parallel to the surface of the first part, and
wherein the second printed circuit board is inclined by the second angle with respect to the plane parallel to the surface of the second part.

15. The display device of claim 7, wherein each of the first and second printed circuit boards have a rectangular shape,
wherein long sides of the rectangle of the first printed circuit board form the first angle with respect to the plane parallel to the surface of the first part, and
wherein long sides of the rectangle of the second printed circuit board form the second angle with respect to the second part.

16. The display device of claim 7, wherein each of the first and second printed circuit boards have a parallelogram shape,
wherein long sides of the parallelogram of the first printed circuit board are sloped by the first angle, and short sides of the parallelogram of the first printed circuit board extend in the second direction, and
wherein long sides of the parallelogram of the second printed circuit board are sloped by the second angle, and short sides of the parallelogram of the second printed circuit board extend in the second direction.

17. The display device of claim 3, wherein positions at which the first flexible circuit films are disposed based on the first point are symmetrical to positions at which the second flexible circuit films are disposed based on the first point,
wherein each of the first flexible circuit films has a length smaller than that of the second flexible circuit film disposed at a corresponding position of the second flexible circuit films.

18. The display device of claim 3, wherein the display panel is bent with respect to the first direction, and the display panel is flat with respect to the second direction.

19. The display device of claim 18, wherein the first flexible circuit films are bent toward a lower surface of the display panel around first bending parts of the first flexible circuit films defined as central parts of the first flexible circuit films based on the second direction,
wherein the second flexible circuit films are bent toward a lower surface of the display panel based on second bending parts of the second flexible circuit films defined as central parts of the second flexible circuit films based on the second direction, and
wherein the printed circuit boards at least partially overlap a lower surface of the display panel.

20. The display device of claim 1, wherein the first point is disposed at a center part of the first side.
